(19) United States
(12) Patent Application Publication
(10) Pub. No.: US 2023/0153067 A1
(43) Pub. Date: May 18, 2023

(54) IN-MEMORY COMPUTING METHOD AND CIRCUIT, SEMICONDUCTOR MEMORY, AND MEMORY STRUCTURE

(71) Applicant: Changxin Memory Technologies, Inc., Hefei City (CN)

(72) Inventors: Heng-Chia CHANG, Hefei City (CN); Li DING, Hefei City (CN)

(73) Assignee: Changxin Memory Technologies, Inc., Hefei City (CN)

(21) Appl. No.: 18/156,552

(22) Filed: Jan. 19, 2023

Related U.S. Application Data
(63) Continuation of application No. PCT/CN2022/070369, filed on Jan. 5, 2022.

(30) Foreign Application Priority Data
Nov. 15, 2021 (CN) 202111347941.9

(51) Int. Cl. G06F 7/50; G11C 11/408; G11C 11/4091; G11C 11/54

(52) U.S. Cl. CPC G06F 7/50; G11C 11/54; G11C 11/4085; G11C 11/4091

(57) ABSTRACT

An in-memory computing method is applied to the in-memory computing circuit. The in-memory computing circuit includes a plurality of first memory cells, a plurality of second memory cells, and a sense amplifier. Level state control is performed on the plurality of first memory cells according to first data to output a first voltage; level state control is performed on the plurality of second memory cells according to second data to output a second voltage; and after receiving a predetermined operation instruction, the sense amplifier receives the first voltage and the second voltage, compares the first voltage with the second voltage, and determines a comparison result of the first data and the second data according to a comparison result of the first voltage and the second voltage.

### CROSS-REFERENCE TO RELATED APPLICATION

This is a continuation of International Patent Application No. PCT/CN2022/070369 filed on Jan. 05, 2022, which claims priority to Chinese Patent Application No. 202111347941.9, filed on Nov. 15, 2021. The disclosure of these applications is hereby incorporated by reference in their entireties

### BACKGROUND

At present, a computing/processing unit and a memory are two completely separate units in an architecture of a mainstream computer. The computing/processing unit reads data from the memory according to an instruction, and stores it back into the memory after computing/processing. However, since the improvement speed in performance of the computing/processing unit is faster than the development speed in performance of a memory unit, the read-write speed of the memory unit becomes an important bottleneck limiting the overall computer performance, that is, a so-called “memory wall”.

In other words, during the operation of a large amount of data, the data needs to be frequently moved between a processor and the memory, resulting in the problems of long operation time and power loss. In order to solve this problem, although the concept of in-memory computing has been proposed in recent years, there is still no unified solution for the specific implementation method of in-memory computing.

### SUMMARY

The present disclosure relates to the technical field of semiconductor circuits, and in particular to an in-memory computing method and circuit, a semiconductor memory, and a memory structure.

Embodiments of the present disclosure provide an in-memory computing method and circuit, a semiconductor memory, and a memory structure, which may implement a comparison operation by means of a memory cell to at least partially improve the problem of slow data processing.

The technical solutions of the present disclosure are implemented as follows.

In a first aspect, the embodiments of the present disclosure provide an in-memory computing method. The in-memory computing circuit may include a plurality of first memory cells, a plurality of second memory cells, and a sense amplifier, the first memory cells having the same quantity as the second memory cells. The method may include the following operations.

Level state control is performed on the plurality of first memory cells according to first data to output a first voltage; level state control is performed on the plurality of second memory cells according to second data to output a second voltage. After receiving a predetermined operation instruction, the sense amplifier receives the first voltage and the second voltage, compares the first voltage with the second voltage, and determines a comparison result of the first data and the second data according to a comparison result of the first voltage and the second voltage.

In a second aspect, the embodiments of the present disclosure provide an in-memory computing circuit, which may include a plurality of first memory cells, a plurality of second memory cells, and a sense amplifier.

The plurality of first memory cells may be configured to perform level state control according to first data to output a first voltage.

The plurality of second memory cells may be configured to perform level state control according to second data to output a second voltage.

The sense amplifier may be configured to receive, after receiving a predetermined operation instruction, the first voltage and the second voltage, compare the first voltage with the second voltage, and determine a comparison result of the first data and the second data according to a comparison result of the first voltage and the second voltage.

In a third aspect, the embodiments of the present disclosure provide a semiconductor memory, which may include the in-memory computing circuit in the second aspect.

In a fourth aspect, the embodiments of the present disclosure provide a memory structure, which may include a base data processor, and the semiconductor memory in the third aspect.

The base data processor may be configured to provide first data and second data.

The semiconductor memory may be configured to perform a comparison operation on the first data and the second data to obtain a comparison result of the first data and the second data.

The base data processor may be further configured to set a predetermined weight; and obtain the comparison result of the first data and the second data, and perform weight processing on the comparison result of the first data and the second data according to the predetermined weight to obtain a target result.

The embodiments of the present disclosure provide an in-memory computing method and circuit, a semiconductor memory, and a memory structure. The in-memory computing method is applied to the in-memory computing circuit. The in-memory computing circuit includes a plurality of first memory cells, a plurality of second memory cells, and a sense amplifier. Level state control is performed on the plurality of first memory cells according to first data to output a first voltage, and level state control is performed on the plurality of second memory cells according to second data to output a second voltage; and after receiving a predetermined operation instruction, the sense amplifier receives the first voltage and the second voltage, compares the first voltage with the second voltage, and determines a comparison result of the first data and the second data according to a comparison result of the first voltage and the second voltage. In this way, by performing level control and level comparison on the memory cells, the comparison operation result of two pieces of data can be obtained, thereby implementing the comparison operation by means of the memory cells and improving the speed and efficiency of data processing.

### BRIEF DESCRIPTION OF THE DRAWINGS

FIG. 1 is a schematic diagram of a computer architecture according to the related art.

FIG. 2 is a schematic diagram of another computer architecture according to the related art.

FIG. 3 is a flowchart of an in-memory computing method according to an embodiment of the present disclosure.

FIG. 4 is a schematic diagram of an architecture of a computing device according to an embodiment of the present disclosure.

FIG. 5 is a schematic diagram of an architecture of a computing device according to the related art.

FIG. 6 is a schematic structural diagram of an in-memory computing circuit according to an embodiment of the present disclosure.

FIG. 7 is a specific schematic structural diagram of an in-memory computing circuit according to an embodiment of the present disclosure.

FIG. 8 is another specific schematic structural diagram of an in-memory computing circuit according to an embodiment of the present disclosure.

FIG. 9 is a schematic structural diagram of a semiconductor memory according to an embodiment of the present disclosure.

FIG. 10 is a schematic structural diagram of a memory structure according to an embodiment of the present disclosure.

FIG. 11 is a schematic diagram of a memory structure according to an embodiment of the present disclosure.

FIG. 12A is a schematic diagram of a logic architecture of a neural network according to an embodiment of the present disclosure.

FIG. 12B is a schematic diagram of a logic architecture of another neural network according to an embodiment of the present disclosure.

### DETAILED DESCRIPTION

The technical solutions in the embodiments of the present disclosure will be clearly and completely described in conjunction with the drawings in the embodiments of the present disclosure. It should be understood that that the specific embodiments described herein are only used to illustrate the related application, but are not intended to limit the disclosure. In addition, it is to be noted that for the convenience of description, only the parts related to the related application are shown in the drawings.

Unless otherwise defined, all technical and scientific terms used herein have the same meaning as commonly understood by those skilled in the art of the present disclosure. The terms used herein are only for the purpose of describing the embodiments of the present disclosure and are not intended to limit the present disclosure.

In the following description, “some embodiments” describes a subset of all possible embodiments, but it should be understood that “some embodiments” may be the same or different subsets of all possible embodiments, and may be combined with each other without conflict.

It is to be noted that the terms “first/second/third” involved in the embodiments of the present disclosure are only used to distinguish similar objects, and do not represent a specific order of the objects. It should be understood that the specific order or precedence of “first/second/third” may be interchangeable under the circumstances permission, so that the embodiments of the disclosure described herein may be implemented in an order except for those illustrated or described herein.

Bitye (Bit): byte.

KiloByte (KB): kilobyte.

ADD: adder.

MULT: multiplier.

Int: a data storage type.

Float: another data storage type.

CPU: Center Processor Unit

SRAM: Static Random Access Memory

DRAM: Dynamic Random Access Memory

MPU: Micro Processor Unit

Petajoule (Pj): an energy unit

SA: sense amplifier, or called sense amplifier module, or sense amplifier circuit.

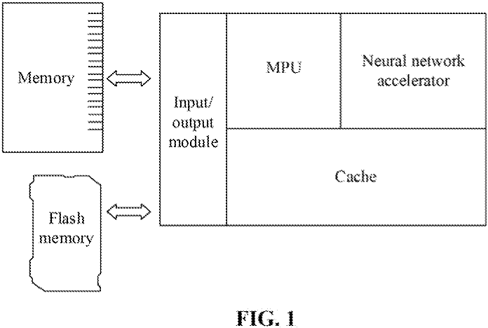

A von Neumann architecture is a classic structure of a computer, and is also a mainstream architecture of the current computer and processor chip. FIG. 1 shows a schematic diagram of a computer architecture according to the related art. As shown in FIG. 1, the von Neumann architecture includes a memory unit (including a memory, a flash memory, etc.), and a computing/processing unit (including a neural network accelerator, a cache, an MPU, an input/output module, etc.). That is, in the classical von Neumann architecture, the computing/processing unit and the memory unit are two completely separate units, the computing/processing unit reads data from the memory unit according to instructions, performs computing/processing on the data, and stores it back into the memory unit.

However, since the improvement speed in performance of the computing/processing unit is faster than the development speed in performance of the memory unit, the read-write speed of the memory unit becomes an important bottleneck limiting the overall computer performance, that is, a so-called “memory wall”. As shown in Table 1, the current DRAM consumes two to three orders of magnitude more energy to read and write 32 Bit data at a time than to compute 32 Bit data, which becomes a bottleneck of the energy efficiency ratio in the overall computing device. In order to solve the problem, the concept of in-memory computing (or called in-memory operation) is proposed.

TABLE 1

| Operation | Energy/pJ | Relative Cost |
|---|---|---|
| 32 Bit Int ADD | 0.1 | 1 |
| 32 Bit Float ADD | 0.9 | 9 |
| 32 Bit Int MULT | 3.1 | 31 |
| 32 Bit Float MULT | 3.7 | 37 |
| 32 Bit 32 KB SRAM | 5 | 50 |
| 32 Bit DRAM | 640 | 6400 |

The main improvement of in-memory computing is that computing is embedded into a memory unit, the memory unit becomes a powerful tool for storage and computing, and the operation is completed while the data is stored/read, which reduces the cost of data access in the computing process. The computing is converted into summation computing with weight, and the weight is stored in the memory unit, so that the memory unit has computing power.

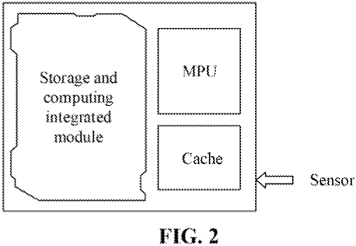

In order to implement in-memory computing, additional storage area and a new computer architecture are required. FIG. 2 shows a schematic diagram of another computer architecture according to the related art. As shown in FIG. 2, the architecture includes a storage-computing integrated module, an MPU and a cache, and the cache is connected to other components through sensors. It may be seen from FIG. 1 and FIG. 2 that the computer architecture is greatly changed, which leads to high implementation cost of in-memory computing and limits the development of in-memory computing.

The embodiments of the present disclosure provide an in-memory computing method, applied to an in-memory computing circuit. The in-memory computing circuit includes a plurality of first memory cells, a plurality of second memory cells, and a sensor amplifier (SA). Level state control is performed on the plurality of first memory cells according to first data to output a first voltage; level state control is performed on the plurality of second memory cells according to second data to output a second voltage; and after receiving a predetermined operation instruction, the SA receives the first voltage and the second voltage, compares the first voltage with the second voltage, and determines a comparison result of the first data and the second data according to a comparison result of the first voltage and the second voltage. In this way, by performing level control and level comparison on the memory cells, the comparison operation result of two pieces of data may be obtained, thereby implementing the comparison operation by means of the memory cells and improving the speed and efficiency of data processing.

The embodiments of the present disclosure will be described in detail below with reference to the accompanying drawings.

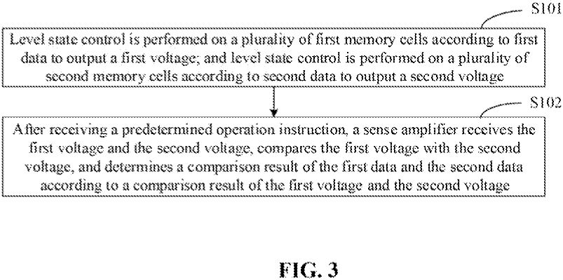

In an embodiment of the present disclosure, FIG. 3 shows a flowchart of an in-memory computing method according to an embodiment of the present disclosure. As shown in FIG. 3, the method may include the following operations S101 and S102.

At S101, level state control is performed on a plurality of first memory cells according to first data to output a first voltage; and level state control is performed on a plurality of second memory cells according to second data to output a second voltage.

It is to be noted that the embodiments of the present disclosure are applied to a computing device, specifically to an in-memory computing circuit. The in-memory computing circuit includes a large number of memory cells and a SA connected to the memory cells.

It should be understood that when different data are stored in a memory cell, the stored charges are different, so that different voltages may be output. Based on such a principle, by controlling level states of the memory cells, a comparison operation of the data is subsequently implemented by means of the level states of the different memory cells.

Assuming that the first data and the second data need to be compared, a plurality of first memory cells and a plurality of second memory cells that are in an idle state are determined in the in-memory computing circuit. Then, level state control is performed on the plurality of first memory cells according to the first data, and level state control is performed on the plurality of second memory cells according to the second data, so as to subsequently complete the comparison operation of data according to the first voltage output by the plurality of first memory cells and the second voltage output by the plurality of second memory cells.

In addition, the quantity of first memory cells and the quantity of second memory cells are generally the same, thereby reducing the occurrence of errors. In the embodiments of the present disclosure, the SA may include, but is not limited to, modules, circuits, and the like that play a role in inductive amplification.

At S102, after receiving a predetermined operation instruction, the sense amplifier (SA) receives the first voltage and the second voltage, compares the first voltage with the second voltage, and determines a comparison result of the first data and the second data according to a comparison result of the first voltage and the second voltage.

It is to be noted that when the first data and the second data requires to be compared, the plurality of first memory cells are controlled to output the first voltage corresponding to the first data, and the plurality of second memory cells are controlled to output the second voltage corresponding to the second data; and then, the comparison result of the first data and the second data may be determined according to the magnitude of the first voltage and the second voltage. In this way, the embodiments of the present disclosure may complete the data comparison operation by means of the memory cells, and there is no need to transfer the data from a memory module to a processor so as to perform the comparison operation using the processor, which improves the speed and efficiency of the data processing and saves a large amount of energy. In addition, the in-memory computing circuit includes the memory cells and the SA, and is of the same structure as an ordinary random dynamic memory function module. In other words, the in-memory computing method in the embodiments of the present disclosure may be applied to a conventional memory module without changing the existing computer architecture, and has high feasibility and low implementation cost.

In some embodiments, the operations that level state control is performed on the plurality of first memory cells according to first data to output a first voltage; and level state control is performed on the plurality of second memory cells according to second data to output a second voltage may include the following operations.

After receiving a preset zero clearing instruction, the plurality of first memory cells and the plurality of second memory cells are controlled to be in a first level state.

The first data and the second data are respectively computed based on a preset bit algorithm to obtain a first quantity and a second quantity.

After receiving a preset write instruction, the first quantity of first memory cells are controlled to be adjusted from the first level state to a second level state, and the second quantity of second memory cells are adjusted from the first level state to the second level state.

It is to be noted that unified zero clearing requires to be performed on the plurality of first memory cells and the plurality of second memory cells, so that the initial level states of the plurality of first memory cells and the plurality of second memory cells are the same, to improve the accuracy of the subsequent data comparison process. Herein, the term “same” also includes “close” within a permissible error range.

That is, when the comparison operation is performed on the first data and the second data, the preset zero clearing instruction and the preset write instruction need to be issued to the in-memory computing circuit in sequence. For the in-memory computing circuit, after receiving the preset zero clearing instruction, the level states of all the first memory cells and all the second memory cells are initialized to the first level state; and after receiving the preset write instruction, the first quantity of first memory cells are adjusted to the second level state and the second quantity of second memory cells are adjusted to the second level state, so as to implement the subsequent comparison process.

Herein, the first quantity is determined based on the first data through a predetermined bit algorithm and the second quantity is determined based on the second data through the predetermined bit algorithm. Specifically, in some embodiments, the operation that the first data and the second data are respectively computed based on a preset bit algorithm to obtain a first quantity and a second quantity may include the following operations.

Values of data to be processed at different data bits are determined.

When a value of the data to be processed at the i-th data bit is a predetermined value, a quantity corresponding to the i-th data bit is determined as mᵢ. Herein, i is a positive integer and mᵢ is a positive integer.

A summation operation is performed on the quantity corresponding to each of all the data bits to obtain a quantity corresponding to the data to be processed.

When the data to be processed is the first data, the first quantity is determined according to the obtained quantity; and when the data to be processed is the second data, the second quantity is determined according to the obtained quantity.

It is to be noted that the data bits are “digits” in a figure and are generally numbered from the right. Taking a common decimal digit as an example, the first data bit is ones digit, the second data bit is tens digit, the third data bit is hundreds digit, and the fourth data bit is thousands digit, etc.

According to the operating principle of an electronic device, the data is generally stored and utilized in a binary form, and therefore the data to be processed is described as binary subsequently in the embodiments of the present disclosure.

For a binary digit, the embodiments of the present disclosure provide different preset quantities mᵢ for different data bits i. Exemplarily, for the binary digit, each data bit from right to left corresponds to 4(2²), 8 (2³), 16 (2⁴)......2ⁱ⁺¹, that is, mᵢ is the (i+1)-th power of 2. For a specific data, if the value of a certain data bit of the data is a preset value, the preset quantity corresponding to the data bit is denoted as one of the “quantities” corresponding to the data to be processed. Finally, after all of the data bits of the data are processed, all the “quantities” corresponding to the data are summed to obtain the final corresponding quantity of the data.

Taking the binary digit “1100” as an example, the preset value is set to “1”, the values of the first bit and the second bit of the binary digit from the right are both “0”, so that there is no any corresponding quantity; the digit of the third bit from the right is “1”, so that the corresponding quantity is 16, that is, the quantity of “2⁴”; and the digit of the fourth bit from the right is “1”, so that the corresponding quantity is 32. Therefore, the total quantity of the binary digit “1001” is (16+32) =48.

Taking the binary digit “1001” as an example, the first digit of the binary digit from the right is “1”, so that the corresponding quantity is 4; the values of the second bit and the third bit from the right are both “0”, so that there is no any corresponding quantity; and the digit of the fourth bit from the right is “1”, so that the corresponding quantity is 32. Therefore, the total quantity of the binary digit “1001” is (4+32) =36.

If the sizes of “1100” and “1001” are computed, it is determined that “1100” corresponds to the first data of 48, “1100” corresponds to the second data of 36. High level is write into 48 first memory cells and high level is write into 36 second memory cells, the unwritten first memory cells and second memory cells are kept at a low level, and switches connected to the first memory cells and second memory cells are turned off after writing.

In the comparison operation, it may be set that the switches of all the first memory cells and the second memory cells are turned on, and the 48 first memory cells and the remaining first memory cells together form the first voltage, and the 36 second memory cells and the remaining second memory cells together form the second voltage. Since the quantity of first memory cells and the quantity of second memory cells are the same, the potential of the first voltage may be higher than that of the second voltage due to the fact that the quantity of high levels written into the first memory cells is greater than the quantity of high levels written into the second memory cells. After the SA receives the first voltage and the second voltage, the high voltage continues to be pulled up and the low voltage continues to be pulled down under the amplification of the SA, and finally the first voltage is output as a high voltage “1”. According to the output result “1”, the value of “1100” is determined to be greater than the value of “1001”.

In this way, based on the embodiments of the present disclosure, the binary digit may be converted into a specific quantity, so that the size of the data may be correlated with the quantity of memory cells, to prepare for the subsequent comparison operation. At the same time, through the preset bit algorithm, the quantity of occupied memory cells is reduced while the size of the binary digit is indicated, and the processing speed is improved, and thus the efficiency of the comparison operation is further improved.

According to the above processing method, if the first data and the second data are the same, the quantities corresponding to the first data and the quantities corresponding to the second data are the same, which may lead to the subsequent first voltage and the second voltage also being the same, thereby resulting in circuit errors. Accordingly, one may be additionally added to the quantity corresponding to the first data to obtain the first quantity, and a quantity corresponding to the second data may be directly used as the second quantity, which avoids the circuit errors in a case where the data are the same. In addition, for the binary data, the preset quantity of the minimum bits is 4, thereby ensuring that there is no case where the respective quantities corresponding to the two data differ by one, and ensuring that the first quantity corresponding to the first data is always different from the second quantity corresponding to the second data.

Therefore, assuming that the first data is “1100”, the first quantity is 49. Assuming that the second data is “1001” as an example, the digit of the first bit of the binary digit from the right is “1”, and the second quantity is 36.

In some embodiments, the operations that when the data to be processed is the first data, the first quantity is determined according to the obtained quantity; and when the data to be processed is the second data, the second quantity is determined according to the obtained quantity include the following operations.

When the data to be processed is the first data, one is added to the obtained quantity to obtain the first quantity; when the data to be processed is the second data, the obtained quantity is determined as the second quantity.

Correspondingly, the first quantity is less than the second quantity when the first data is less than the second data. The first quantity is greater than the second quantity when the first data is greater than or equal to the second data.

It is to be noted that in order to avoid the first quantity and the second quantity being the same, a variety of methods may be used, and the above is only one example and does not constitute a limitation of the embodiments of the present disclosure.

In some embodiments, the in-memory computing circuit is implemented by means of memory devices such as a DRAM, an SRAM, etc. Both the DRAM and the SRAM consist of a large amount of repeating memory cells, each of which is connected to a word line and a bit line respectively. A voltage signal on the word line may control the opening or closing of a transistor, and then data information stored in a capacitor is read through the bit line or the data information is written into the capacitor for storage through the bit line.

The in-memory computing circuit may further include a plurality of first word lines, a plurality of second word lines, a word-line position control circuit, a first bit line, and a second bit line. The plurality of first word lines is connected to the plurality of first memory cells one by one, and the plurality of second word lines is connected to the plurality of second memory cells one by one. The plurality of first memory cells is jointly connected to the first bit line, and the plurality of second memory cells is jointly connected to the second bit line.

The plurality of first word lines and a plurality of second word lines are arranged oppositely each other relative to the SA, the plurality of first memory cells on the plurality of first word lines are connected to one terminal of the SA through the first bit line, and the plurality of second memory cells on the plurality of second word lines are connected to the other terminal of the SA through the second bit line. Therefore, the SA may obtain the first voltage output by the plurality of first memory cells and the second voltage output by the plurality of second memory cells.

Based on the structure of the above in-memory computing circuit, in a specific embodiment, the operation that the plurality of first memory cells and the plurality of second memory cells are controlled to be in a first level state may include the following operations.

The plurality of first word lines and the plurality of second word lines are controlled to be in an activated state by the word-line position control circuit, so that the plurality of first memory cells and the plurality of second memory cells are in a conducting state.

Zero clearing processing is performed on the plurality of first memory cells in the conducting state through the first bit line, and the second bit line performs zero clearing processing on the plurality of second memory cells in the conducting state, so that the plurality of first memory cells and the plurality of second memory cells are in the first level state.

In another specific embodiment, the operation that the first quantity of first memory cells are controlled to be adjusted from the first level state to a second level state, and the second quantity of second memory cells are adjusted from the first level state to the second level state may include the following operations.

The word-line position control circuit controls the first quantity of first word lines to be in the activated state, and controls the first bit line to perform write processing on the first memory cells connected to the first word lines in the activated state, so that the first quantity of first memory cells are adjusted from the first level state to the second level state.

The word-line position control circuit controls the second quantity of second word lines to be in the activated state, and controls the second bit line to perform write processing on the second memory cells connected to the second word lines in the activated state, so that the second quantity of second memory cells are adjusted from the first level state to the second level state.

It may be seen from the above that the writing process of the memory cell is as follows. When data needs to be written into a memory cell, the position control circuit controls a corresponding word line to be in the activated state first, so that all memory cells on the word line are in the conducting state; and then, the data “0” or “1” is written into the specified memory cell using a corresponding bit line. Here, the zero clearing process may be regarded as writing data 0 into the memory cell. The data writing based on the first bit line and the second bit line is controlled by a writing circuit having the same structure as that of an ordinary random dynamic memory function module, which will not be elaborated herein.

In another specific embodiment, the operation that the sense amplifier receives the first voltage and the second voltage includes the following operations.

The plurality of first word lines and the plurality of second word lines are controlled to be in the activated state by the word-line position control circuit, so that the plurality of first memory cells and the plurality of second memory cells are in the conducting state.

The sense amplifier is controlled to perform read processing on the plurality of first memory cells in the conducting state through the first bit line, so as to receive the first voltage output by the plurality of first memory cells; and the sense amplifier is controlled to perform read processing on the plurality of second memory cells in the conducting state through the second bit line, so as to receive the second voltage output by the plurality of second memory cells.

It is to be noted that the readout process of the memory cell is as follows. When the data stored in a memory cell needs to be read out, the word-line position control circuit controls a corresponding word line to be in the activated state first, so that all the memory cells on the word line are in the conducting state; and then a corresponding bit line is controlled to be in the activated state, so that the charge in the specified memory cell flows to the SA, that is, the SA receives the voltage output by the memory cell.

In some embodiments, the first level state is a low level state and the second level state is a high level state. The low level state may be a voltage below V_{DD}/2 and the high level state may be a voltage above V_{DD}/2. V_{DD} is a supply voltage connected to the SA.

Correspondingly, the operation that a comparison result of the first data and the second data is determined according to a comparison result of the first voltage and the second voltage may include the following operations.

In a case where the first voltage is higher than the second voltage, the sense amplifier outputs a first result value. Herein, the first result value is used to indicate that the first data is greater than or equal to the second data. In a case where the first voltage is lower than the second voltage, the sense amplifier outputs a second result value. Herein, the second result value is used to indicate that the first data is less than the second data.

In summary, the embodiments of the present disclosure provide at least an in-memory computing method for implementing the comparison operation. Specifically, if it is desired to implement the comparison operation of the first data and the second data, first, two relatively independent areas are determined from the memory module, that is, the plurality of first word lines and the plurality of second word lines are determined, then all the first word lines and the second word lines are activated, zero clearing processing is performed on the memory cells connected to the word lines in the activated state, and all the first word lines and the second word lines are turned off. Then, the first data and the second data are converted into the first quantity and the second quantity respectively, the first quantity of the first word lines and the second quantity of the second word lines are activated respectively, the data “1” is written into the memory cells connected to the word lines in the activated state, and all the first word lines and the second word lines are turned off.

During the comparison performed by the SA, all the first word lines and the second word lines are activated, all the first memory cells and the second memory cells are turned on, both the first memory cells into which “1” is written and the first memory cells that keep a zero clearing state transmit a potential state to the first bit line, the first voltage is formed on the first bit line by charge sharing of each first memory cell, and the first voltage is transmitted to the SA.

At the same time, both the second memory cells into which “1” is written and the second memory cells that keep a zero clearing state transmit a potential state to the second bit line, the second voltage is formed on the second bit line by charge sharing of each first memory cell, and the second voltage is transmitted to the SA.

After the sense amplifier receives the first voltage and the second voltage, the high voltage continues to be pulled up and the low voltage continues to be pulled down according to the amplification, so that a first voltage amplification result-“high voltage or low voltage” is output through the first bit line, and the comparison result is determined according to the amplification result of the first voltage.

If the first voltage is high voltage and the second voltage is low voltage, then a comparison result of the high voltage of “1” is output.

If the first voltage is low voltage and the second voltage is high voltage, a comparison result of the low voltage of “0” is output.

The comparison result may also be determined according to the amplification result of the second voltage output by the second bit line.

Therefore, the sizes of the first data and the second data may be determined by the output result of the SA.

In this way, the data comparison operation may be completed by means of the memory cells to obtain the comparison operation result, and there is no need to transfer the data from the memory module to the processor so as to perform the comparison operation using the processor, which improves the speed and efficiency of the data processing and saves a large amount of energy. In other words, the data that needs a large amount of comparisons in the computer may be stored into a memory first, and the memory may directly perform the comparison operation to obtain the comparison result. In this way, the operation time and power consumption can be greatly reduced, and even the data information may not enter the MPU and cache first.

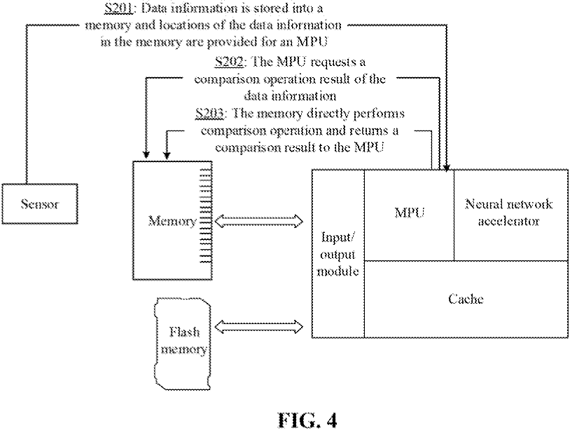

In addition, the in-memory computing method provided by embodiments of the present disclosure may be applied to the existing computer architecture, and has high feasibility and low implementation cost. FIG. 4 shows a schematic diagram of an architecture of a computing device according to an embodiment of the present disclosure. As shown in FIG. 4, the computer architecture still follows the classic von Neumann architecture, and the entire working process includes the following operations S201, S202, S203.

At S201, data information is stored into a memory and locations of the data information in the memory are provided to an MPU.

At S202, the MPU requests a comparison operation result of the data information.

At S203, the memory directly performs the comparison operation and returns a comparison result to the MPU.

In this way, during the comparison operation on the data information, there is no need to transfer the data information from the memory to the MPU, then perform the comparison operation through the MPU, and then transfer the comparison result to the memory. Instead, the memory directly completes the comparison operation and returns the comparison result to the MPU, which reduces a large amount of the energy consumption and the processing time.

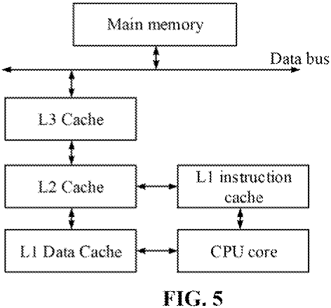

Taking a computing device using a three-level cache mechanism in the related art as an example, FIG. 5 shows a schematic diagram of an architecture of a computing device according to the related art. As shown in FIG. 5, the memory structure includes a Main Memory, a L3 Cache, an L2 Cache, an L1 Data Cache (L1d Cache), a L1 instruction cache (L1i Cache), and a CPU Core. The main memory and the L3 cache are both connected to a data bus, and the connections of other modules may be seen in the figure.

Table 2 shows clock cycles required to access several major locations. As shown in Table 2, access to memory each time takes about 240 clock cycles. That is, if the comparison operation needs to be performed on the data, the processor needs to access the memory multiple times to obtain the data, and then perform the comparison operation. In the embodiments of the present disclosure, the comparison operation is performed on the data using the memory, thereby saving the time for the processor to access the memory, that is, about 240*(N-1) clock cycles may be saved each time when the data comparison operation is performed using the memory. Herein, N is the number of access.

TABLE 2

| | |
|---|---|
| Data destination | Required clock cycle |
| Register | Smaller than or equal to 1 |
| L1d Cache | About 3 |
| L2 Cache | About 14 |
| Main memory | About 240 |

The embodiments of the present disclosure provide an in-memory computing method and circuit. The in-memory computing circuit includes a plurality of first memory cells, a plurality of second memory cells, and a sense amplifier (SA). Level state control is performed on the plurality of first memory cells according to the first data to output the first voltage; level state control is performed on the plurality of second memory cells according to the second data to output the second voltage; and after receiving the predetermined operation instruction, the SA receives the first voltage and the second voltage, compares the first voltage with the second voltage, and determines the comparison result of the first data and the second data according to the comparison result of the first voltage and the second voltage. In this way, the comparison operation result of the two pieces of data is obtained by performing level control and level comparison on the memory cells, thereby implementing the comparison operation by means of the memory cells and improving the speed and efficiency of data processing.

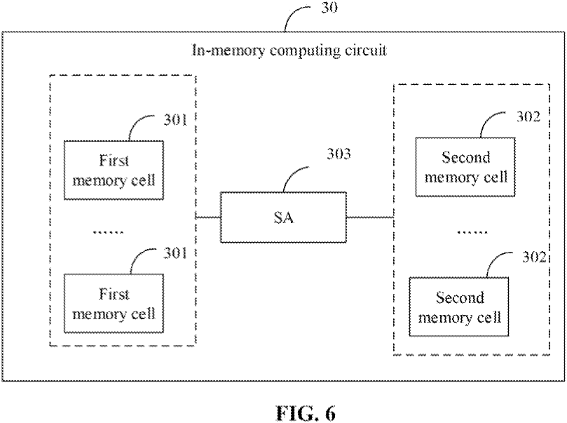

In another embodiment of the present disclosure, FIG. 6 shows a schematic structural diagram of an in-memory computing circuit 30 according to an embodiment of the present disclosure. As shown in FIG. 6, the in-memory computing circuit 30 includes: a plurality of first memory cells 301, a plurality of second memory cells 302, and a sense amplifier (SA) 303.

The plurality of first memory cells 301 is configured to perform level state control according to first data to output a first voltage.

The plurality of second memory cells 302 is configured to perform level state control according to second data to output a second voltage.

The SA 303 is configured to receive, after receiving a predetermined operation instruction, the first voltage and the second voltage, compare the first voltage with the second voltage, and determine a comparison result of the first data and the second data according to a comparison result of the first voltage and the second voltage.

It is to be noted that embodiments of the present disclosure provide the in-memory computing circuit 30, applied to a memory device. The memory device includes, but is not limited to, a DRAM, a SRAM, and the like. In addition, the in-memory computing circuit 30 is configured to implement the aforementioned in-memory computing method.

The in-memory computing circuit 30 includes the plurality of first memory cells 301, the plurality of second memory cells 302, and the SA 303. The level state of the plurality of first storage cells 301 may indicate the first data, and the level state of the plurality of second storage cells 302 may indicate the second data. Therefore, when a comparison operation needs to be performed on the first data and the second data, the plurality of first memory cells 301 are controlled to output the first voltage to the SA 303, the plurality of second memory cells 302 are controlled to output the second voltage to the SA 303, and the SA 303 compares the first voltage with the second voltage, so as to determine the comparison result of the first data and the second data. In this way, the comparison operation can also be implemented by means of an ordinary memory function module without changing the architecture of the existing computer, which can greatly save the energy consumed by the comparison operation, and at the same time improve the speed of comparison operation, and comprehensively improve the computing performance.

In some embodiments, the plurality of first memory cells 301 are specifically configured to control a first quantity of first memory cells 301 to be in a second level state and control other first memory cells 301 other than the first quantity to be in a first level state. The plurality of second memory cells 302 are specifically configured to control a second quantity of second memory cells 302 to be in the second level state and control other second memory cells 302 other than the second quantity to be in the first level state.

It is to be noted that the first quantity is determined according to the first data, and the second quantity is determined according to the second data, the specific determination method of which refers to the above and will not be elaborated in the embodiments of the present disclosure. Therefore, for the plurality of first memory cells 301, the first quantity of memory cells are in the second level state and the other quantity of memory cells are in the first level state. For the plurality of second memory cells 302, the second quantity of memory cells are in the second level state and the other quantity of memory cells are in the first level state. In this way, the first voltage jointly output by the plurality of first memory cells 301 and the second voltage jointly output by the plurality of second memory cells 302 may indicate the first data and the second data respectively, and thus the sizes of the first data and the second data may be compared by means of the plurality of first memory cells 301 and the plurality of second memory cells 302.

In a specific embodiment, the complete control process of the level state is as follows. Unified zero clearing processing is performed on the plurality of first memory cells 301 and the plurality of second memory cells 302, so that all the plurality of first memory cells 301 and all the plurality of second memory cells 302 are in the first level state. Then, the first quantity of first memory cells 301 are adjusted to be in the second level state, and the second quantity of second memory cells 302 are adjusted to be in the second level state, thereby completing control of the level states of the plurality of first memory cells 301 and the plurality of second memory cells 302.

The level control process is described below in combination with the specific circuit structure.

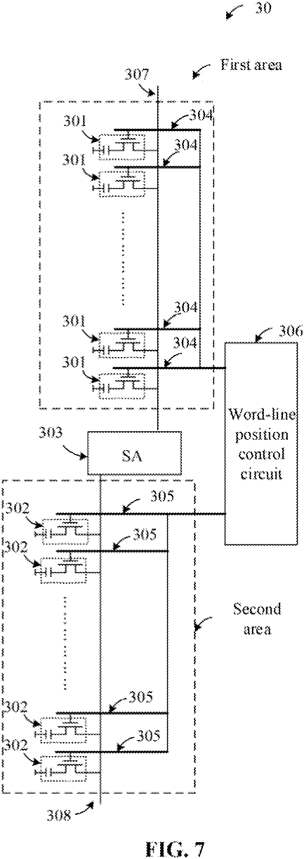

In some embodiments, FIG. 7 shows a specific schematic structural diagram of an in-memory computing circuit according to an embodiment of the present disclosure. As shown in FIG. 7, for the sake of illustration, the area in which the plurality of first memory cells 301 are located is remarked as a first area and the area in which the plurality of second memory cells 302 are located is remarked as a second area.

As shown in FIG. 7, the in-memory computing circuit 30 further includes a plurality of first word lines 304, a plurality of second word lines 305, a word-line position control circuit 306, a first bit line 307, and a second bit line 308. The plurality of first word lines 304 is connected to the plurality of first memory cells 301 one by one, the plurality of second word lines 305 is connected to the plurality of second memory cells 302 one by one, the plurality of first memory cells 301 is jointly connected to the first bit line 307, the plurality of second word lines 302 is connected to the second bit line 308, and the first bit line 307 and the second bit line 308 are both connected to the SA 303.

Correspondingly, the word-line position control circuit 306 is configured to control, after receiving a preset zero clearing instruction, the plurality of first memory cells 304 and the plurality of second memory cells 305 to be in the first level state, so that the plurality of first memory cells 301 and the plurality of second memory cells 302 are in a conducting state.

The first bit line 307 is configured to perform zero clearing processing on the plurality of first memory cells 301 in the conducting state, so that the plurality of first memory cells 301 are in the first level state.

The second bit line 308 is configured to perform zero clearing processing on the plurality of second memory cells 302 in the conducting state, so that the plurality of second memory cells 302 are in the first level state. In this way, through the zero clearing processing, both the plurality of first memory cells 301 and the plurality of second memory cells 302 are in the first level state.

Similarly, in some embodiments, the word-line position control circuit 306 is further configured to after receiving a preset write instruction, control the first quantity of first word lines 304 to be in the activated state, and control the second quantity of second word lines 305 to be in the activated state.

The first bit line 307 is further configured to perform write processing on the first memory cells 301 connected to the first word lines 304 in the activated state, so that the first quantity of first memory cells 301 are adjusted from the first level state to the second level state.

The second bit line 308 is further configured to perform write processing on the second memory cells 302 connected to the second word lines 305 in the activated state, so that the second quantity of second memory cells 302 are adjusted from the first level state to the second level state.

In this way, through the write processing, both the first quantity of first memory cells 301 and the second quantity of second memory cells 302 are in the second level state.

In other words, the first word lines 304 are word lines connected to the first memory cells 301, the second word lines 305 are word lines connected to the second memory cells 302, the word-line position control circuit 306 is configured to control the word lines in the activated/closed state, and the first bit line 307 and the second bit line 308 are configured to write data into the memory cells on the word lines in the activated state. The data writing based on the first bit line 307 and the second bit line 308 is controlled by a writing circuit having the same structure as that of the ordinary random dynamic memory function module, which will not be elaborated herein.

In addition, as shown in FIG. 7, a memory cell includes one capacitor and one transistor, which is also referred to as a 1T1C structure, but this does not constitute a limitation to the embodiments of the present disclosure.

It is to be noted that the writing process of the memory cell is as follows. when data needs to be written into a memory cell, the position control circuit controls the corresponding word lines to be in the activated state first, so that all memory cells on the word lines are in the conducting state; and then, the data “0” or “1” is written into the specified memory cells using the corresponding bit line. Here, the zero clearing process may be regarded as writing data 0 into the memory cell.

In some embodiments, the word-line position control circuit 306 is further configured to control, after receiving a preset comparison instruction, the plurality of first word lines 304 and the plurality of second word lines 305 to be in the activated state, so that the plurality of first memory cells 301 and the plurality of second memory cells 302 are in the conducting state.

The SA 303 is further configured to perform, after receiving the preset comparison instruction, read processing on the plurality of first memory cells 301 and the plurality of second memory cells 302 in the conducting state, receive the first voltage output by the plurality of first memory cells 301 through the first bit line, and receive the second voltage output by the plurality of second memory cells 302 through the second bit line.

It is to be noted that the readout process of the memory cell is as follows. When the data stored in the memory cell needs to be read out, the word-line position control circuit controls all the first word lines and all the second word lines to be in the activated state first, so that all the first memory cells and all the second memory cells are in the conducting state; and then, one terminal of the SA receives the first voltage jointly applied by all the first memory cells, and the other terminal of the SA receives the second voltage jointly applied by all the second memory cells. Accordingly, the SA performs comparison and amplification on the first voltage and the second voltage to obtain a comparison result, and can determine a comparison result of the first data and the second data according to the comparison result, so that in-memory computing, especially in-memory computing for the comparison operation, may be partially implemented using the existing computer architecture, the processing speed is increased, the energy is saved, the feasibility is high, and the implementation cost is low.

In a specific embodiment, the SA 303 is further configured to output a first result value in a case where the first voltage is higher than the second voltage; or output a second result value in a case where the first voltage is lower than the second voltage.

Here, the first result value is used to indicate that the first data is greater than or equal to the second data, and the second result value is used to indicate that the first data is less than the second data.

It is to be noted that the SA 303 performs inductive amplification on the first voltage and the second voltage, and determines the first result value or the second result value according to the magnitude of the first voltage and the magnitude of the second voltage. It should be understood that the above is only one implementation method for determining the comparison result and does not constitute a limitation to the embodiments of the present disclosure, and the specific method for determining the comparison result needs to be matched with the method of determining the first quantity/second quantity.

In some embodiments, the SA 303 includes a first terminal and a second terminal, and each of the plurality of first memory cells 301 and each of the plurality of second memory cells 302 include a memory switch transistor.

The first terminal of the SA 303 is connected to a drain terminal of the memory switch transistor in each of the plurality of first memory cells 301 through the first bit line 307, and the second terminal of the SA 303 is connected to a drain terminal of the memory switch transistor in each of the plurality of second memory cells 302 through the second bit line 308.

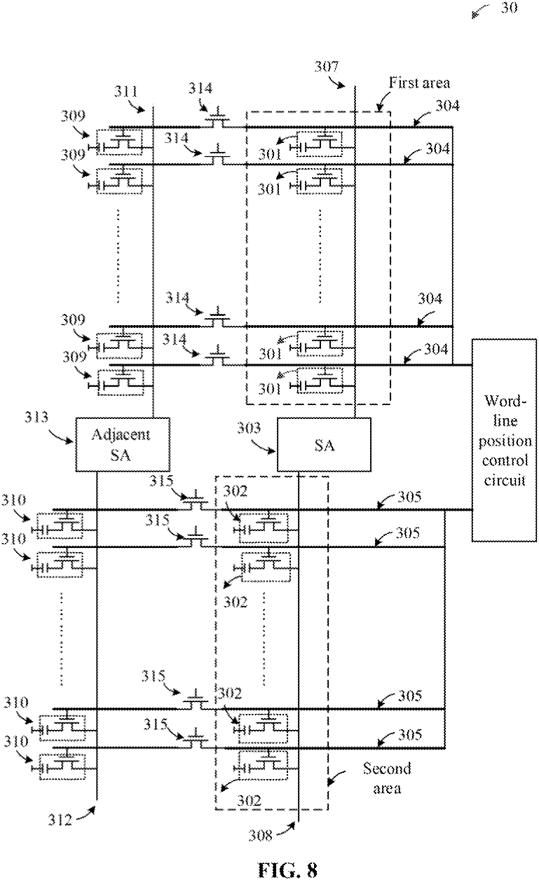

In some embodiments, FIG. 8 shows another specific schematic structural diagram of an in-memory computing circuit according to an embodiment of the present disclosure. As shown in FIG. 8, the in-memory computing circuit 30 further includes a plurality of first adjacent memory cells 309, a plurality of second adjacent memory cells 310, a first adjacent bit line 311, a second adjacent bit line 312, and an adjacent SA 313. The plurality of first adjacent memory cells 309 is connected to the adjacent SA 313 through the first adjacent bit line 311 and the plurality of second adjacent memory cells 310 is connected to the adjacent SA 313 through the second adjacent bit line 312.

In other words, the plurality of first adjacent memory cells 309 are connected to the plurality of first word lines 304 one by one, and the plurality of second adjacent memory cells 310 are connected to the plurality of second word lines 305 one by one. That is, one first word line 304 is connected to one first memory cell 301 and one first adjacent memory cell 309 at the same time, and one second word line 305 is connected to one second memory cell 302 and one second adjacent memory cell 310 at the same time.

In this case, if all of the first word lines 304/second word lines 305 are turned on, it may result in the data of other memory cells (that is, the plurality of first adjacent memory cells 309/the plurality of second adjacent memory cells 310) connected to the same word line being corrupted. In order to solve the problem, an isolation switch transistor for isolating the memory cells may be arranged between two adjacent memory cells on the same word line, thereby preventing other data information from being corrupted.

Exemplarily, the a-th first isolation switch transistor 314 is arranged between the a-th first adjacent memory cell 309 and the a-th first memory cell 301 located on the same first word line 304. The b-th second isolation switch transistor 315 is arranged between the b-th second adjacent memory cell 310 and the b-th second memory cell 302 located on the same second word line 305. Herein, a and b are both positive integers.

In addition, each of the plurality of first adjacent memory cells 309 includes a memory switch transistor, and each of the plurality of second adjacent memory cells 310 includes a memory switch transistor. In some embodiments, each of the plurality of first adjacent memory cells 309 includes a memory switch transistor, and each of the plurality of second adjacent memory cells 310 includes a memory switch transistor.

The drain terminal of the a-th first isolation switch transistor 314 is connected to the gate terminal of a memory switch transistor in the a-th first memory cell 301 through the first word line 304, and the source terminal of the a-th first isolation switch transistor 314 is connected to the gate terminal of a memory switch transistor in the a-th first adjacent memory cell 309 through the first word line 304.

The drain terminal of the b-th second isolation switch transistor 315 is connected to the gate terminal of a memory switch transistor in the b-th second memory cell 302 through the second word line 305, and the source terminal of the b-th second isolation switch transistor 315 is connected to the gate terminal of a memory switch transistor in the b-th second adjacent memory cell 310 through the second word line 305.

In this way, by adding a transistor between the two memory cells at the adjacent locations, the data in the adjacent memory cells may be prevented from being corrupted after all the word lines are turned on.

In summary, the embodiments of the present disclosure provide a in-memory computing circuit, which completes the comparison operation by means of the memory cell. Based on the in-memory computing circuit shown in FIG. 7, the comparison operation may include the following steps.

(1) During operations performed by the processor, data information required for comparison operation is classified into two categories, for example the first data and the second data.

(2) Zero clearing is performed on the designated area location of the sense amplifier circuit (that is, SA) in the memory (DRAM) first, that is, zero clearing is performed on the memory cells in the first area and the second area.

(3) A plurality of word lines is activated using the first data and the second data according to the bit weight, and the data “1” is written into the memory cells corresponding to the sense amplifier circuit (SA) in the activated word lines, and all the word lines are turned off.

(4) When the comparison result needs to be obtained, all the word lines in the first area and in the second area are activated, and the memory cells in the activated word lines output the first voltage and the second voltage to the sense amplifier circuit, and a comparison result is determined after the operation of the sense amplifier circuit.

In this way, the comparison operation may be performed by means of the memory cell without transferring the data information to the processor. At the same time, the in-memory computing circuit may be applied to the existing computer architecture, and has high feasibility and low implementation cost.

The embodiments of the present disclosure provide an in-memory computing circuit. The in-memory computing circuit includes: a plurality of first memory cells, configured to perform level state control according to the first data to output the first voltage; a plurality of second memory cells, configured to perform level state control according to the second data to output the second voltage; and a sense amplifier (SA), configured to receive, after receiving a predetermined operation instruction, the first voltage and the second voltage, compare the first voltage with the second voltage, and determine the comparison result of the first data and the second data according to the comparison result of the first voltage and the second voltage. In this way, by performing level control and level comparison on the memory cells, a comparison operation result of the two pieces of data may be obtained, thereby implementing the comparison operation by means of the memory cells, and thus improving the speed and efficiency of data processing.

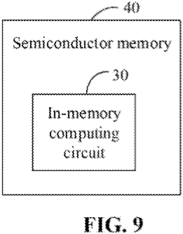

In yet another embodiment of the present disclosure, FIG. 9 shows a schematic structural diagram of a semiconductor memory 40 according to an embodiment of the present disclosure. As shown in FIG. 9, the semiconductor memory 40 includes the aforementioned in-memory computing circuit 30.

Since the semiconductor memory 40 includes the aforementioned in-memory computing circuit 30, by performing level control and level comparison on the memory cells, the comparison operation result of two pieces of data may be obtained, thereby implementing the comparison operation by means of the memory cells, and thus improving the speed and efficiency of data processing.

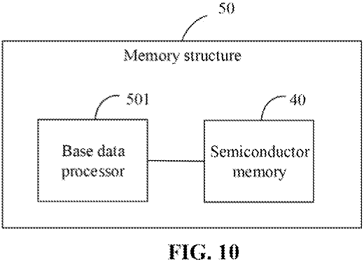

In still yet another embodiment of the present disclosure, FIG. 10 shows a schematic structural diagram of a memory structure 50 according to an embodiment of the present disclosure. As shown in FIG. 10, the memory structure 50 includes a base data processor 501 and a semiconductor memory 40.

The base data processor 501 is configured to provide first data and second data.

The semiconductor memory 40 is configured to perform a comparison operation on the first data and the second data to obtain a comparison result of the first data and the second data.

It is to be noted that the memory structure may be applied to any device having a computing function, such as a computer, a smartphone, a laptop computer, a handheld computer, a server, and the like. The memory structure 50 may include the base data processor 501 and the semiconductor memory 40. In a case where the base data processor 501 provides the first data and the second data, the comparison operation of the first data and the second data can be implemented by the semiconductor memory 40. In this way, the comparison operation may be implemented by means of the ordinary memory function module without changing the existing computer architecture, which can greatly save the energy consumed by the comparison operation, improve the speed of comparison operation, and comprehensively improve the computing performance.

In some embodiments, the base data processor is further configured to set a predetermined weight; and

obtain the comparison result of the first data and the second data, and performing weight processing on the comparison results of the first data and the second data according to the predetermined weight to obtain a target result.

It is to be noted that the base data processor may further set weights for different comparison results to implement some more complex operations, especially applied in a neural network algorithm.

In some embodiments, the memory structure includes a high bandwidth memory (also referred to as High Bandwidth Memory (HBM)). At this time, the base data processor 501 may be a Base die and the semiconductor memory 40 may be a DRAM die.

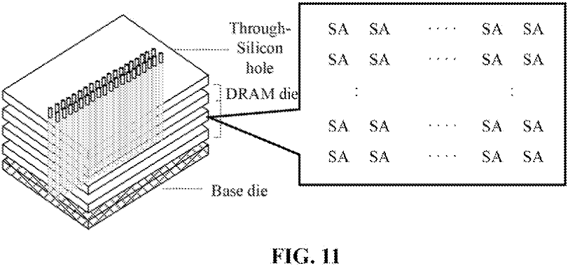

It is to be noted that the HBM is a high-performance interface configured to support data throughput of a memory device, the performance of which far exceeds the memories in a conventional form. FIG. 11 shows a schematic diagram of a memory structure according to an embodiment of the present disclosure. An HBM structure includes: through-silicon via (TSV), DRAM dies, and a Base die. Compared with a conventional memory structure, the HBM structure has a tighter stacking structure, and the HBM structure has better data processing performance relative to the conventional memory structure.

Based on the HBM architecture, an algorithm operation is performed using the Base die, and meanwhile, data storage and comparison are performed using the DRAM die, and the final result is transmitted to the processor to implement in-memory computing.

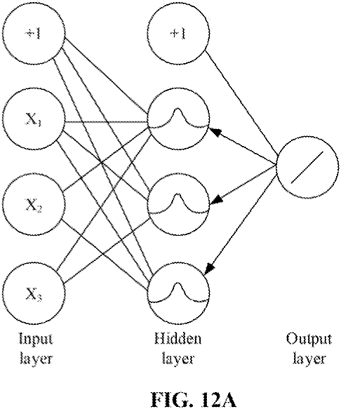

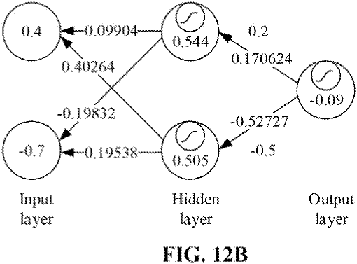

For example, the algorithm operation may be a Back Propagation (BP) Neural Network algorithm operation, whose algorithm structure is shown in FIG. 12A and FIG. 12B. The algorithm structure includes at least one input layer, at least one hidden layer, and an output layer, and involves a large quantity of comparison operations, and the contributions of the structures for different comparison operations to the whole network are different. At this time, the Base die of the HBM may store the preset weight and copy the information to an in-memory computing circuit containing the SA in the DRAM die for the comparison operation.

In addition, the relevant symbols and values in FIG. 12A and FIG. 12B are a conventional example and are not relevant to the in-memory computing process, and thus do not affect the understanding and implementation of the embodiments of the present disclosure and will not be elaborated herein.

The embodiments of the present disclosure provide a memory structure, which includes a base data processor, configured to provide the first data and the second data; and a semiconductor memory, configured to perform the comparison operation on the first data and the second data to obtain the comparison result of the first data and the second data. In this way, by performing level control and level comparison on the memory cells, the comparison operation result of two pieces of data may be obtained, thereby implementing the comparison operation by means of the memory cells, and thus improving the speed and efficiency of data processing.

The above are only preferred embodiments of the present disclosure, and are not intended to limit the protection scope of the present disclosure.

It is to be noted that in the present disclosure, the terms “including”, “containing” or any other variation thereof are intended to cover non-exclusive inclusion, so that a process, method, article or device including a series of elements includes not only those elements, but also other elements not explicitly listed, or elements inherent to the process, method, article or device. Without more restrictions, an element defined by the sentence “including a/an ...” does not exclude the existence of other identical elements in the process, method, article, or device including the element.

The above numbers of the embodiments of the present disclosure are only for description, and do not represent the advantages or disadvantages of the embodiments.

The methods disclosed in the several method embodiments provided in the present disclosure may be combined arbitrarily without conflict to obtain new method embodiments.

The features disclosed in the several product embodiments provided in the present disclosure may be combined arbitrarily without conflict to obtain new product embodiment.

The features disclosed in several method or device embodiments provided in the present disclosure may be combined arbitrarily without conflict to obtain new method embodiments or device embodiments.

The above are only the specific implementation modes of the present disclosure and not intended to limit the scope of protection of the present disclosure. Any variations or replacements apparent to those skilled in the art within the technical scope disclosed by the disclosure shall fall within the scope of protection of the present disclosure. Therefore, the scope of protection of the present disclosure shall be subject to the scope of protection of the claims.

### INDUSTRIAL APPLICABILITY

Embodiments of the present disclosure provide an in-memory computing method and circuit, a semiconductor memory, and a memory structure. The in-memory computing method is applied to the in-memory computing circuit. The in-memory computing circuit includes a plurality of first memory cells, a plurality of second memory cells, and a sense amplifier. Level state control is performed on the plurality of first memory cells according to first data to output a first voltage; level state control is performed on the plurality of second memory cells according to second data to output a second voltage; and after receiving a predetermined operation instruction, the sense amplifier receives the first voltage and the second voltage, compares the first voltage with the second voltage, and determines a comparison result of the first data and the second data according to a comparison result of the first voltage and the second voltage. In this way, by performing level control and level comparison on the memory cells, the comparison operation result of two pieces of data may be obtained, thereby implementing the comparison operation by means of the memory cells, and thus improving the speed and efficiency of data processing.

1. An in-memory computing method, applied to an in-memory computing circuit, the in-memory computing circuit comprising a plurality of first memory cells, a plurality of second memory cells, and a sense amplifier, the first memory cells having the same quantity as the second memory cells, the method comprising:
performing level state control on the plurality of first memory cells according to first data to output a first voltage; and performing level state control on the plurality of second memory cells according to second data to output a second voltage; and
after receiving a predetermined operation instruction, receiving, by the sense amplifier, the first voltage and the second voltage, comparing the first voltage with the second voltage, and determining a comparison result of the first data and the second data according to a comparison result of the first voltage and the second voltage.

2. The in-memory computing method of claim 1, wherein the performing level state control on the plurality of first memory cells according to first data to output a first voltage; and performing level state control on the plurality of second memory cells according to second data to output a second voltage comprises:
after receiving a preset zero clearing instruction, controlling the plurality of first memory cells and the plurality of second memory cells to be in a first level state;
computing the first data and the second data respectively based on a preset bit algorithm to obtain a first quantity and a second quantity; and
after receiving a preset write instruction, controlling the first quantity of first memory cells to be adjusted from the first level state to a second level state, and controlling the second quantity of second memory cells to be adjusted from the first level state to the second level state.

3. The in-memory computing method of claim 2, wherein the in-memory computing circuit further comprises a plurality of first word lines, a plurality of second word lines, a word-line position control circuit, a first bit line, and a second bit line, the plurality of first word lines being connected to the plurality of first memory cells one by one, the plurality of second word lines being connected to the plurality of second memory cells one by one, the plurality of first memory cells being jointly connected to the first bit line, and the plurality of second memory cells being jointly connected to the second bit line;
wherein the controlling the plurality of first memory cells and the plurality of second memory cells to be in a first level state comprises:
controlling, by the word-line position control circuit, the plurality of first word lines and the plurality of second word lines to be in an activated state, so that the plurality of first memory cells and the plurality of second memory cells are in a conducting state; and
performing, by the first bit line, zero clearing processing on the plurality of first memory cells in the conducting state, and performing, by the second bit line, zero clearing processing on the plurality of second memory cells in the conducting state, so that the plurality of first memory cells and the plurality of second memory cells are in the first level state.

4. The in-memory computing method of claim 3, wherein the controlling the first quantity of first memory cells to be adjusted from the first level state to a second level state, and controlling the second quantity of second memory cells to be adjusted from the first level state to the second level state comprises:
controlling, by the word-line position control circuit, the first quantity of first word lines to be in the activated state, and controlling the first bit line to perform write processing on the first memory cells connected to the first word lines in the activated state, so that the first quantity of first memory cells are adjusted from the first level state to the second level state; and
controlling, by the word-line position control circuit, the second quantity of second word lines to be in the activated state, and controlling the second bit line to perform write processing on the second memory cells connected to the second word lines in the activated state, so that the second quantity of second memory cells are adjusted from the first level state to the second level state.

5. The in-memory computing method of claim 3, wherein the receiving, by the sense amplifier, the first voltage and the second voltage comprises:
controlling, by the word-line position control circuit, the plurality of first word lines and the plurality of second word lines to be in the activated state, so that the plurality of first memory cells and the plurality of second memory cells are in the conducting state; and
controlling the sense amplifier to perform read processing on the plurality of first memory cells and the plurality of second memory cells in the conducting state, receive, through the first bit line, the first voltage output by the plurality of first memory cells, and receive, through the second bit line, the second voltage output by the plurality of second memory cells.

6. The in-memory computing method of claim 2, wherein the computing the first data and the second data respectively based on a preset bit algorithm to obtain a first quantity and a second quantity comprises:
determining values of data to be processed at different data bits;
when a value of the data to be processed at an i-th data bit is a predetermined value, determining a quantity corresponding to the i-th data bit as mᵢ; wherein i is a positive integer and mᵢ is a positive integer;
performing a summation operation on a quantity corresponding to each of the data bits to obtain a quantity corresponding to the data to be processed; and
determining the first quantity according to a obtained quantity when the data to be processed is the first data; and determining the second quantity according to the obtained quantity when the data to be processed is the second data.

7. The in-memory computing method of claim 6, wherein the determining the first quantity according to the obtained quantity when the data to be processed is the first data; and determining the second quantity according to the obtained quantity when the data to be processed is the second data comprises:
when the data to be processed is the first data, adding one to the obtained quantity to obtain the first quantity; and
when the data to be processed is the second data, determining the obtained quantity as the second quantity;
correspondingly, wherein the first quantity is less than the second quantity when the first data is less than the second data; and
the first quantity is greater than the second quantity when the first data is greater than or equal to the second data.

8. The in-memory computing method of claim 6, wherein mᵢ is a (i+1)-th power of 2.

9. The in-memory computing method of claim 1, wherein the first level state is a low level state and the second level state is a high level state;
correspondingly, wherein the determining a comparison result of the first data and the second data according to a comparison result of the first voltage and the second voltage comprises:
in a case where the first voltage is higher than the second voltage, outputting, by the sense amplifier, a first result value; wherein the first result value indicates that the first data is greater than or equal to the second data; and
in a case where the first voltage is less than the second voltage, outputting, by the sense amplifier, a second result value; wherein the second result value indicates that the first data is less than the second data.

10. An in-memory computing circuit, comprising:
a plurality of first memory cells, configured to perform level state control according to first data to output a first voltage;
a plurality of second memory cells, configured to perform level state control according to second data to output a second voltage; and
a sense amplifier, configured to receive, after receiving a predetermined operation instruction, the first voltage and the second voltage, compare the first voltage with the second voltage, and determine a comparison result of the first data and the second data according to a comparison result of the first voltage and the second voltage.

11. The in-memory computing circuit of claim 10, wherein,
the plurality of first memory cells are specifically configured to control a first quantity of first memory cells to be in a second level state and control other first memory cells other than the first quantity to be in a first level state;
the plurality of second memory cells are specifically configured to control a second quantity of second memory cells to be in the second level state and control other second memory cells other than the second quantity to be in the first level state;
wherein the first quantity is determined according to the first data, and the second quantity is determined according to the second data.

12. The in-memory computing circuit of claim 10, wherein the in-memory computing circuit further comprises a plurality of first word lines, a plurality of second word lines, a word-line position control circuit, a first bit line, and a second bit line, the plurality of first word lines being connected to the plurality of first memory cells one by one, and the plurality of second word lines being connected to the plurality of second memory cells one by one;
wherein the word-line position control circuit is configured to control, after receiving a preset zero clearing instruction, the plurality of first word lines and the plurality of second word lines to be in an activated state, so that the plurality of first memory cells and the plurality of second memory cells are in a conducting state;
the first bit line is configured to perform zero clearing processing on the plurality of first memory cells in the conducting state, so that the plurality of first memory cells are in the first level state; and
the second bit line is configured to perform zero clearing processing on the plurality of second memory cells in the conducting state, so that the plurality of second memory cells are in the first level state.

13. The in-memory computing circuit of claim 12, wherein
the word-line position control circuit is further configured to after receiving a preset write instruction, control the first quantity of first word lines to be in the activated state, and control the second quantity of second word lines to be in the activated state;
the first bit line is further configured to perform write processing on the first memory cells connected to the first word lines in the activated state, so that the first quantity of first memory cells are adjusted from the first level state to the second level state; and
the second bit line is further configured to perform write processing on the second memory cells connected to the second word lines in the activated state, so that the second quantity of second memory cells are adjusted from the first level state to the second level state.

14. The in-memory computing circuit of claim 12, wherein,
the word-line position control circuit is further configured to control, after receiving a preset comparison instruction, the plurality of first word lines and the plurality of second word lines to be in the activated state, so that the plurality of first memory cells and the plurality of second memory cells are in the conducting state; and
the sense amplifier is further configured to after receiving the preset comparison instruction, perform read processing on the plurality of first memory cells and the plurality of second memory cells in the conducting state, receive the first voltage output by the plurality of first memory cells through the first bit line, and receive the second voltage output by the plurality of second memory cells through the second bit line.

15. The in-memory computing circuit of claim 10, wherein,
the sense amplifier is further configured to output a first result value in a case where the first voltage is higher than the second voltage; or output a second result value in a case where the first voltage is lower than the second voltage;
wherein the first result value indicates that the first data is greater than or equal to the second data, and the second result value indicates that the first data is less than the second data.

16. The in-memory computing circuit of claim 10, wherein the sense amplifier comprises a first terminal and a second terminal, and each of the plurality of first memory cells and each of the plurality of second memory cells comprises a memory switch transistor; and
the first terminal of the sense amplifier is connected to a drain terminal of the memory switch transistor in the plurality of first memory cells through the first bit line, and the second terminal of the sense amplifier is connected to a drain terminal of the memory switch transistor in the plurality of second memory cells through the second bit line.

17. The in-memory computing circuit of claim 16, wherein the in-memory computing circuit further comprises a plurality of first adjacent memory cells, a plurality of second adjacent memory cells, a first adjacent bit line, a second adjacent bit line, and an adjacent sense amplifier, the plurality of first adjacent memory cells being connected to the adjacent sense amplifier through the first adjacent bit line, and the plurality of second adjacent memory cells being connected to the adjacent sense amplifier through the second adjacent bit line;
the in-memory computing circuit further comprises a plurality of first isolation switch transistors and a plurality of second isolation switch transistors;
an a-th first isolation switch transistor is arranged between an a-th first adjacent memory cell and an a-th first memory cell that are located on a same first word line;
a b-th second isolation switch transistor is arranged between a b-th second adjacent memory cell and a b-th second memory cell that are located on a same second word line;
wherein both a and b are positive integers.

18. The in-memory computing circuit of claim 17, wherein each of the plurality of first adjacent memory cells and each of the plurality of second adjacent memory cells comprises a memory switch transistor;
a drain terminal of the a-th first isolation switch transistor is connected to a gate terminal of a memory switch transistor in the a-th first memory cell through the first word line, and a source terminal of the a-th first isolation switch transistor is connected to a gate terminal of a memory switch transistor in the a-th first adjacent memory cell through the first word line; and
a drain terminal of the b-th second isolation switch transistor is connected to a gate terminal of a memory switch transistor in the b-th second memory cell through the second word line, and a source terminal of the b-th second isolation switch transistor is connected to a gate terminal of a memory switch transistor in the b-th second adjacent memory cell through the second word line.

19. A semiconductor memory, comprising the in-memory computing circuit of claim 10.

20. A memory structure, comprising a base data processor and the semiconductor memory of claim 19; wherein,
the base data processor is configured to provide first data and second data; and
the semiconductor memory is configured to perform a comparison operation on the first data and the second data to obtain a comparison result of the first data and the second data;
wherein the base data processor is further configured to set a predetermined weight; and obtain the comparison result of the first data and the second data, and perform weight processing on the comparison result of the first data and the second data according to the predetermined weight to obtain a target result.
